(19) United States
(12) Patent Application Publication
(10) Pub. No.: US 2026/0123452 A1
(43) Pub. Date: Apr. 30, 2026

(54) BONDING STRUCTURES FORMED USING SELECTIVE SURFACE TREATMENT OF COPPER BUMPS AND METHODS OF FORMING THE SAME

(71) Applicant: Taiwan Semiconductor Manufacturing Company Limited, Hsinchu (TW)

(72) Inventors: Hui-Ting Lin, Tainan City (TW); Amram Eitan, Hsinchu (TW); Yu-Wen Sun, Kaohsiung City (TW); Jen-Hao Liu, Zhunan Township (TW); Chih-Yuan Chiu, Zhudong Township (TW)

(21) Appl. No.: 18/926,674

(22) Filed: Oct. 25, 2024

(51) Int. Cl. H01L 23/00; H01L 21/48; H01L 23/498

(52) U.S. Cl. CPC H10W 70/097; H10W 70/66; H10W 72/01212; H10W 72/01215; H10W 72/01261; H10W 72/01271; H10W 72/016; H10W 72/072; H10W 72/07236; H10W 72/222; H10W 72/241; H10W 72/252; H10W 90/724

(57) ABSTRACT

Methods of fabricating semiconductor devices and resulting bonded structures. An embodiment method includes tilting a plasma nozzle to an angle with respect to a substrate. The method includes applying, with the plasma nozzle, an oxidation gas onto a first side of at least one substrate-side copper bump on the substrate, forming an oxidized copper sidewall on the first side of the substrate-side copper bump. The method includes bonding a semiconductor chip to the substrate using the substrate-side copper bump.

### BACKGROUND

In the manufacture of semiconductor devices, the bonding of semiconductor chips to substrates may impact the overall performance and reliability of the final product. This bonding process typically involves the use of metallic interconnections, such as copper bumps, which serve as the primary means of establishing electrical and mechanical connections between the chip and the substrate. The quality of these bonding connections may be influenced by several factors, including the surface condition of the copper bumps, the wetting behavior of solder materials, and the environmental conditions during bonding.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A-1D illustrate an example semiconductor device in various stages of a bonding process.

FIG. 2 is a diagram illustrating an example system for selective surface treatment of copper bumps.

FIG. 3A-3G are vertical cross-sectional views of the semiconductor device during example processes for fabricating the semiconductor device using selective surface treatment according to an embodiment.

FIG. 4A-4D are vertical cross-sectional views of the semiconductor device during example processes for fabricating the semiconductor device using selective surface treatment according to an embodiment.

FIG. 5A-5G are vertical cross-sectional views of the semiconductor device during example processes for fabricating the semiconductor device using selective surface treatment according to an embodiment.

FIG. 6A-6D are vertical cross-sectional views of the semiconductor device during example processes for fabricating the semiconductor device using selective surface treatment according to an embodiment.

FIG. 7 is a vertical cross-sectional view of the semiconductor device that illustrates various angles at which a plasma nozzle can be directed for selective surface treatment of copper bumps.

FIG. 8 illustrates a flow diagram of an example method for fabricating a semiconductor device.

FIG. 9 illustrates a flow diagram of an example method for fabricating a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Achieving optimal solder wetting and minimizing defects, such as cold joints and solder bridges, may be useful in bonding semiconductor chips to ensure strong and reliable connections. Various surface treatment techniques may enhance the bonding process. The surface treatment techniques may target the selective oxidation and deoxidation of copper surfaces to improve solderability and to control the formation of intermetallic compounds during reflow. These surface treatments may be particularly useful in advanced semiconductor packaging, where fine pitch and high-density interconnects are increasingly common.

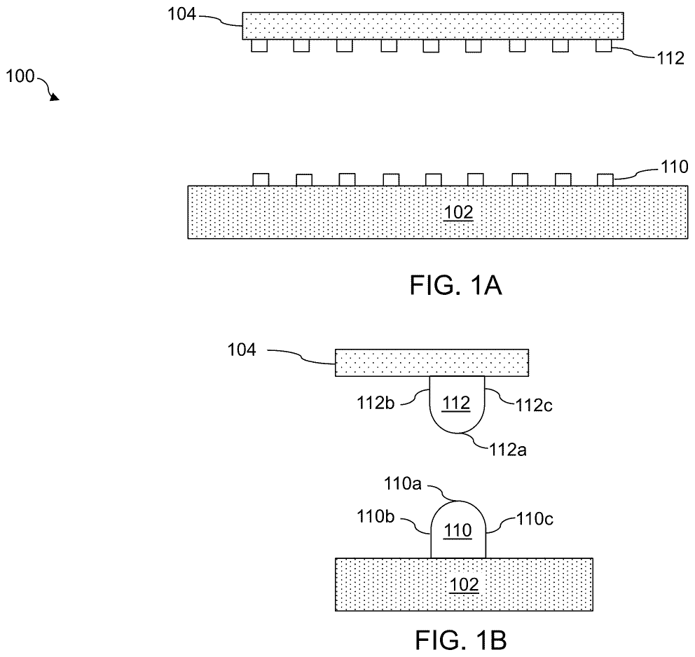

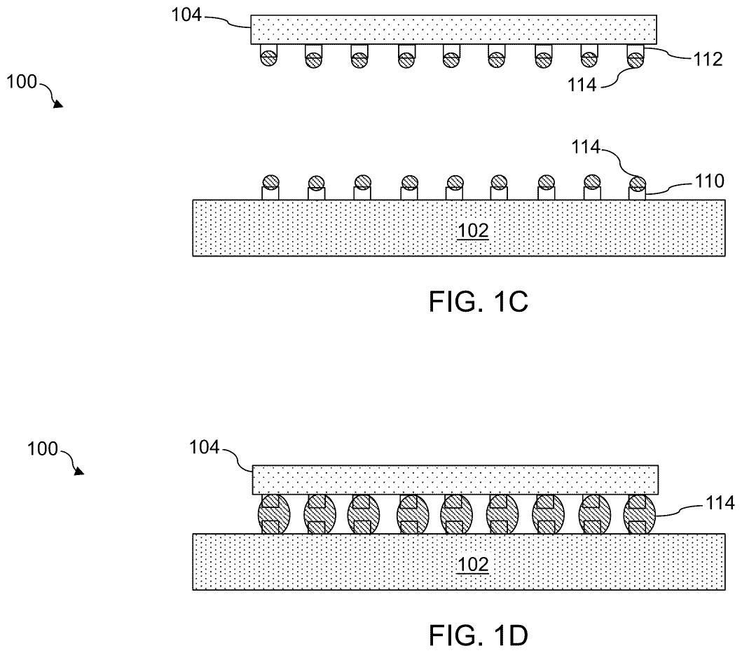

FIG. 1A-1D illustrate an example semiconductor device 100 in various stages of a bonding process. FIG. 1A is a vertical cross-sectional view of the semiconductor device 100 prior to the bonding process. The semiconductor device 100 includes a substrate 102, a semiconductor chip 104, a number of substrate-side copper bumps 110 on the substrate 102, and a number of chip-side copper bumps 112 on the semiconductor chip 104.

The substrate 102 may serve as the foundation for mounting and interconnecting various electronic components including semiconductor chips 104 or passive electronic components (not shown). The substrate 102 may be made from materials such as silicon, ceramic, or organic laminates, depending on the specific application and performance requirements. The substrate 102 may be configured with a patterned metallization layer, which includes conductive traces and pads that facilitate electrical connections between the semiconductor chip 104 and external circuitry. For example, the substrate 102 may be an interposer or redistribution layer.

The substrate 102 may also include additional features, such as underfill materials or passivation layers, to improve mechanical stability and protect the interconnects from environmental stressors. The alignment and surface preparation of the substrate 102 may be configured to ensure proper bonding with the semiconductor chip, particularly in fine-pitch applications where precision and cleanliness are paramount.

The semiconductor chip 104 may include integrated circuits that perform various computational, memory, or sensing functions. Typically fabricated from a silicon wafer, the semiconductor chip 104 may be diced into individual units, each of which may include networks of transistors, resistors, inductors, capacitors, and interconnects.

The surface of the semiconductor chip 104 may be provided with the chip-side copper bumps 112. The chip-side copper bumps 112 may be strategically located to align with corresponding substrate-side copper bumps 110 on the substrate 102. The chip-side copper bumps 112 and substrate-side copper bumps 110 may serve as the primary means of electrical and mechanical connection between the semiconductor chip 104 and the substrate 102. The chip-side copper bumps 112 and substrate-side copper bumps 110 may ensure that electrical signals may be transmitted efficiently and reliably. The surface of the semiconductor chip 104 may also be protected with a passivation layer to prevent contamination and mechanical damage during handling and assembly.

The type of semiconductor chip 104 may vary widely depending on the intended application of the semiconductor device 100. For example, the semiconductor chip 104 may be a microprocessor, which serves as the central processing unit (CPU) in a computer, performing arithmetic, logic, and control operations. Alternatively, the semiconductor chip 104 may be a memory chip, such as dynamic random-access memory (DRAM) or flash memory, which stores data for retrieval by electronic devices.

In more specialized applications, the semiconductor chip 104 may be an application-specific integrated circuit (ASIC), designed for a particular task such as digital signal processing in communications equipment. Another example is a system-on-chip (SoC), which integrates multiple functions, including CPU, graphics processing unit (GPU), and memory, onto a single chip, commonly used in smartphones and other compact electronic devices. Each of these types of semiconductor chips 104 may be bonded using precise alignment to the substrate 102 to ensure optimal performance and durability in their respective applications.

FIG. 1B is a vertical cross-sectional view of an example substrate-side copper bump 110 and an example chip-side copper bump 112. The substrate-side copper bump 110 and chip-side copper bump 112 may have any appropriate shape. For example, the shape of the substrate-side copper bump 110 and chip-side copper bump 112 may be a truncated sphere or a rounded dome, often referred to as a “stud” or “pill” shape. This shape results from the electroplating or deposition process used to form the substrate-side copper bump 110 and chip-side copper bump 112 on the respective semiconductor chip 104 and substrate 102.

In some embodiments, the substrate-side copper bump 110 and chip-side copper bump 112 may be made entirely of copper due to copper's electrical conductivity, thermal properties, and mechanical strength. In some embodiments, the substrate-side copper bump 110 and chip-side copper bump 112 may have a surface layer of copper over another core material. For example, such surface layer copper over another core material may occur in processes where copper is electroplated over a base material to form the substrate-side copper bump 110 and/or chip-side copper bump 112.

In some embodiments, each of the substrate-side copper bump 110 and chip-side copper bump 112 may have a broad base where the copper bump is attached to the substrate 102 or semiconductor chip 104, providing a stable foundation. The substrate-side copper bump 110 has a substrate-side copper bump top 110a, and the substrate-side copper bump top 110a may be rounded or slightly flattened, depending on the fabrication method and the target application. Similarly, the chip-side copper bump 112 has a chip-side copper bump top 112a, and the chip-side copper bump top 112a may be rounded or slightly flattened, depending on the fabrication method and the target application.

In some embodiments, the substrate-side copper bump 110 has sidewalls 110b and 110c that curve smoothly from the base to the top 110a. The chip-side copper bump 112 has sidewalls 112b and 112c that curve smoothly from the base to the top 112a. Curving sidewalls (110b, 110c, 112b, 112c) may give the substrate-side copper bump 110 and chip-side copper bump 112 a dome-like appearance. The height and diameter of the substrate-side copper bump 110 and chip-side copper bump 112 may be in the range of a few micrometers to tens of micrometers, depending on the pitch (distance between adjacent bumps) and the specific design targets of the semiconductor device 100. The rounded shape of the substrate-side copper bump 110 and chip-side copper bump 112 may be useful to facilitate uniform solder wetting during the bonding process, ensure good mechanical contact, and provide reliable electrical connections between the semiconductor chip 104 and the substrate 102.

As shown in FIG. 1B, the substrate-side copper bump 110 includes a first side 110a and a second side 110b opposite the first side 110a. Similarly, the chip-side copper bump 112 includes a first side 112a and a second side 112b opposite the first side 112a. A selective surface treatment may be applied to each of the substrate-side copper bump 110 and chip-side copper bump 112 to enable solder wetting at the same side of each of the substrate-side copper bump 110 and chip-side copper bump 112 during bonding. By enabling solder wetting at the same side, the amount of solder applied may be increased to prevent cold joints without inducing solder bridge defects. This may be particularly useful in applications with a large package size and small pitch.

A cold joint occurs in instances in which the solder fails to melt completely and form a proper bond between a component and a bond pad (i.e., between the substrate-side copper bump 110 and chip-side copper bump 112). A cold joint may lead to weak or unreliable electrical connections. A solder bridge defect may occur in instances in which excess solder creates an unintended connection between adjacent contacts. A solder bridge defect may potentially cause short circuits (i.e., unintended electrical connections). Increasing the amount of solder reduces the chances of cold joints. However, the increase in the amount of solder increases the likelihood of solder bridge defects; this dilemma may be mitigated by selective surface treatment that promotes asymmetric wetting.

For example, consider the substrate-side copper bump 110. Selective surface treatment may deoxidize surfaces of the substrate-side copper bump 110. The substrate-side copper bump 110 may have an oxidized copper sidewall on the first side 110b of the substrate-side copper bump 110 and deoxidized copper sidewall on the second side 110c of the substrate-side copper bump 110. The substrate-side copper bump 110 may also have a deoxidized top surface 110a.

Solder may flow over deoxidized copper more easily than over oxidized copper. The oxidized copper layer may confine the solder (i.e., decreased solder wettability flow). As a result, during a solder bonding process, solder may preferentially flow over the second side 110c of the substrate-side copper bump 110, which is deoxidized, rather than the first side 110b of the substrate-side copper bump 110, which is oxidized, causing asymmetric wetting. Sufficient electrical and mechanical connection may be ensured by solder flowing over the second side 110c of the substrate-side copper bump 110, while a solder bridge defect may be avoided by a reduced amount of solder of the first side 110b of the substrate-side copper bump 110.

Similarly, selective surface treatment may be applied to the chip-side copper bump 112. The chip-side copper bump 112 may be aligned opposite the substrate-side copper bump 110 in the vertical direction during the bonding process such that an electrical and mechanical connection between the substrate-side copper bumps 110 and chip-side copper bumps 112 may be formed by the bonding process.

The chip-side copper bump 112 may have an oxidized copper sidewall on the first side 112b of the chip-side copper bump 112 and deoxidized copper sidewall on the second side 112c of the chip-side copper bump 112. The chip-side copper bump 112 may also have a deoxidized top surface 112a.

As a result, during a solder bonding process, solder may preferentially flow over the second side 112c of the chip-side copper bump 112 rather than the first side 112b of the chip-side copper bump. The resulting asymmetric wetting reflects the asymmetric wetting on the substrate-side copper bump 110.

In some embodiments, the oxidized copper first sidewall 110b on the substrate-side copper bump 110 has an oxide layer with a thickness of A nanometers, and the deoxidized copper second sidewall 110c on the substrate-side copper bump 110 has an oxide layer with a thickness of B nanometers, and the difference in oxide thickness, A minus B, is at least 3 nanometers. This differential oxide thickness may ensure a significant contrast in the surface chemistry between the oxidized and deoxidized first sidewall 110b and second sidewall 110c, which directly influences the solder flow and adhesion during the bonding process.

The thicker oxide layer on the oxidized sidewall (A) provides a higher resistance to solder wetting, helping to confine the solder to specific regions of the bump and prevent it from spreading uncontrollably. Conversely, the thinner oxide layer on the deoxidized sidewall (B) promotes better solder wetting, ensuring a strong and uniform bond on the targeted areas. The difference of at least 3 nanometers between A and B causes a sufficient disparity in the wetting behavior, which may be useful to ensure the overall quality and reliability of the semiconductor device's interconnects.

FIG. 1C shows the semiconductor device 100 after solder 114 is applied to the substrate-side copper bumps 110 and the chip-side copper bumps 112. The solder 114, typically composed of a tin-based alloy, such as tin-silver-copper (SnAgCu (sometimes referred to as SAC)) or tin-lead (Sn—Pb), is selectively deposited onto the surfaces of the substrate-side copper bump 110 and chip-side copper bump 112 to facilitate the subsequent bonding process. The solder 114 may be applied using any suitable method, including screen printing, electroplating, or solder paste deposition, each chosen based on the precision and thickness requirements of the application.

Once applied, the solder 114 may form a uniform coating over the deoxidized surfaces of the substrate-side copper bump 110 and chip-side copper bump 112, ensuring good wetting characteristics and a reliable metallurgical bond during reflow.

The solder thickness may controlled to achieve a target standoff height between the semiconductor chip 104 and the substrate 102. Additionally, the solder's composition and flux content may be selected to minimize void formation and to ensure robust connections with minimal defects.

FIG. 1D shows the semiconductor device 100 after completion of the solder bonding process. The resulting solder-coated substrate-side copper bumps 110 and chip-side copper bumps 112 are aligned and reflowed, where the solder 114 melts and solidifies, forming a strong, conductive joint that securely bonds the semiconductor chip 104 to the substrate 102. The solder 114 bonding enables the electrical and mechanical integration of the device 100 components. The asymmetric wetting that results from the selective surface treatment of the substrate-side copper bumps 110 and chip-side copper bumps 112 reduces the chances of both solder bridge defects and cold joints.

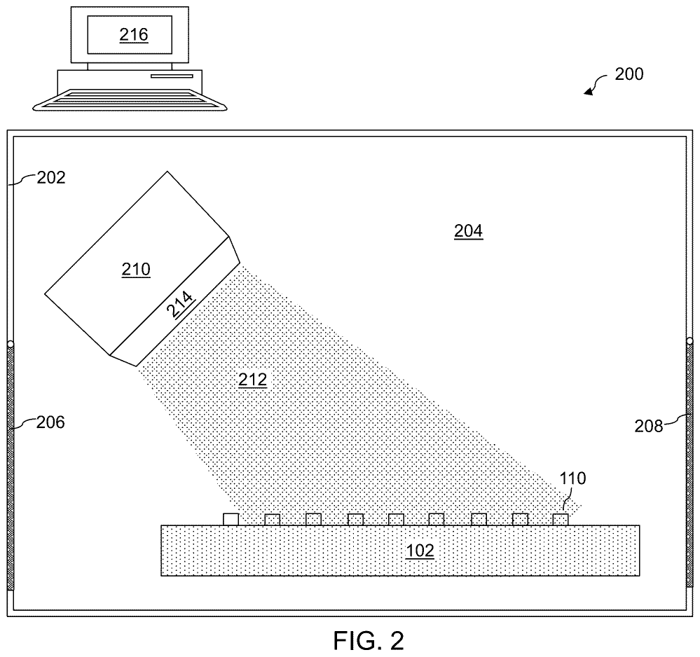

FIG. 2 is a diagram illustrating an example system 200 for selective surface treatment of copper bumps (e.g., substrate-side copper bump 110 and chip-side copper bump 112). FIG. 2 shows the substrate 102 and the substrate-side copper bumps 110 positioned for treatment. The system 200 may also be used for selective surface treatment of the semiconductor chip 104 and the chip-side copper bumps 112.

The system 200 includes a process chamber (202, 206, 208) including a chamber enclosure 202 and an ambient control system configured to provide a low-oxygen ambient 204 within a volume that is spatially bounded by the chamber enclosure 202. The low-oxygen ambient 204 is an environment with an oxygen concentration of less than 200 parts per million (ppm). A suitable mechanism such as an ambient gas supply nozzle, an exhaust port, and/or a vacuum pumping port may be provided to maintain the composition and the pressure of the low-oxygen ambient 204 at a pre-determined level.

The chamber enclosure 202 may comprise a first opening and a second opening. A first door 206 may be provided at the first opening in a manner that provides sealing of a volume that is enclosed by the chamber enclosure 202. A second door 208 may be provided at the second opening in a manner that provides sealing of the volume that is enclosed by the chamber enclosure 202. Suitable door actuation mechanisms may be provided for the first door 206 and the second door 208 so that the first door 206 and the second door 208 may be opened and closed to provide transport of semiconductor packages and packaging substrates in and out of the chamber enclosure 202. The first door 206 and the second door 208 may be located on opposite sides of the chamber enclosures 202, or the first door 206 and the second door 208 may be arranged differently, or merged as a single door.

A plasma treatment system 210 is provided within the process chamber (202, 206, 208). The plasma treatment system 210 is configured to generate a plasma jet 212. The plasma treatment system 210 comprises a plasma nozzle 214 configured to generate a respective atmospheric pressure plasma jet 212 containing ions of a reducing gas, i.e., a gas that may combine with oxygen atoms to de-oxidize a surface. The plasma nozzle 214 of the plasma treatment system 210 may be configured such that the plasma jet 212 is directed toward the substrate-side copper bumps 110 on the substrate 102.

The plasma jet 212 direction of the plasma treatment system 210 may, or may not, be tilted with respect to the vertical direction, and may be tilted with respect to the horizontal direction. The tilt angle of each plasma jet 210 direction relative to the vertical direction may be generally in a range from 0 degree to +85 degrees, such as from 15 degrees to 60 degrees, although lesser and greater tilt angles may also be used. Generally, the tilt angle may be a fixed angle, or may be a in-situ controllable variable angle.

The plasma treatment system 210 may form a reducing plasma (i.e., a deoxidizing plasma) by generating the plasma jet 212, which is an atmospheric pressure plasma jet (APPJ). Generally, an atmospheric pressure plasma jet (APPJ) may be generated by passing a gas (such as air, argon, or helium) through a high voltage electrical discharge. The resulting plasma is composed of highly reactive species, such as ions and radicals, which may be used for a variety of industrial and research applications.

APPJ treatment is a process used in semiconductor fabrication to clean, activate and treat surfaces. APPJ uses a low-temperature plasma, generated at atmospheric pressure, to modify the surface chemistry of a material. Plasma is a state of matter that is created when a gas is ionized, or when its atoms are stripped of some of their electrons, creating mixture of ions, electrons, and neutral particles. Plasma may be created at a variety of pressures, including atmospheric pressure.

The APPJ system typically comprises a plasma generator, a gas feed system, and a nozzle that directs the plasma onto the surface to be treated. The plasma may be generated by introducing a gas, such as argon or oxygen, into the plasma generator, where it is excited by an electrical discharge. The plasma generator may create a plasma, which is then directed through the nozzle and onto the surface to be treated. APPJ may be a non-contact, low-temperature, and low-pressure process, which makes APPJ compatible with a wide range of materials and may be easily integrated into existing semiconductor fabrication processes.

The generated high-energy plasma of an APPJ system may remove contaminants and particles from surfaces, providing a clean surface for subsequent processing steps. The plasma may modify the surface chemistry of a material, increasing the reactivity of the material and making the material more suitable for subsequent processing steps. The plasma may also be used to deposit thin films or change the surface morphology of a material. The plasma may be used to remove or passivate surface oxides and other unwanted surface layers. The plasma may also be used to change the surface energy of a material to improve the adhesion of subsequent layers.

According to an aspect of the present disclosure, the APPJ from the plasma treatment system 210 is used for selective surface treatment of the substrate-side copper bumps 110 and chip-side copper bumps 112. Specifically, ions in each plasma jet 212 may be directed toward the substrate-side copper bumps 110 and chip-side copper bumps 112 to clean the surfaces of the substrate-side copper bumps 110 and chip-side copper bumps 112. The high energy species in the plasma may interact with the surfaces, thereby breaking down, and removing, contaminants on the substrate-side copper bumps 110 and chip-side copper bumps 112.

In some embodiments, each plasma jet 212 uses ions of a reducing gas to reduce and/or remove contaminants (such as oxygen or water vapor) on the surfaces of the substrate-side copper bump 110 and chip-side copper bump 112. A reducing gas is mixed with a respective plasma jet 212, and the resulting reactive species are directed towards the surfaces to be cleaned, effectively reducing and removing the contaminants on the surfaces.

Reducing gases that may be used to for each plasma jet 212 from the plasma treatment system 210 may include, but are not limited, to hydrogen, various hydride gases (such as methane, ammonia, acetylene, etc.), carbon monoxide, and various volatile compounds including hydrogen radicals. Hydrogen gas is a strong reducing agent and may be used to remove oxides, sulfates, and other contaminants from surfaces. Methane is a hydrocarbon gas that may be used to remove carbon-based by contaminants from surfaces. Ammonia is a weak reducing agent that may be used to remove nitrides and other nitrogen-based contaminants from surfaces.

Carbon dioxide may be used to remove organic contaminants from surfaces. Nitrogen may be used to remove oxygen-based contaminants. Propane is a hydrocarbon gas that may be used to remove carbon-based contaminants from surfaces. In some other embodiments, non-reducing gases such as argon and helium may be optionally used to cool down the plasma, and/or to protect the plasma jet and to improve the plasma properties.

Generally, any ion that acts as a reducing agent may be used. Each atmospheric pressure plasma jet 212 generated by the plasma treatment system 210 does not need to be at an “atmospheric” pressure, but may be any pressure that may be used to generate the condition of an atmospheric pressure plasma jet known in the art. Generally, the plasma treatment process may be performed in the low-oxygen ambient 204, which has an oxygen partial pressure that is lower than, for example, 17 kPa.

The system 200 may include a process controller 216. The process controller 216 includes a processor and memory in communication with the processor. The process controller 216 may be loaded with a program that controls loading and positioning of the semiconductor chip 104 and the substrate 102, and/or controls the direction, the coverage, the duration, and/or the magnitude of the plasma jet 212 generated by the plasma treatment system 210. Surface oxides may be removed from the copper-containing surfaces of the substrate-side copper bump 110 and chip-side copper bump 112.

The plasma treatment process may be performed by directing the plasma jet 212 to the substrate-side copper bump 110 and/or chip-side copper bump 112. In some embodiments, the plasma nozzle 214 is directed at the substrate-side copper bump 110 along a downward non-horizontal direction while the substrate 102 is oriented along a horizontal direction during the plasma treatment process. In some embodiments, the plasma jet 212 may simultaneously clean one of the substrate-side copper bumps 110 and one of the chip-side copper bumps 112.

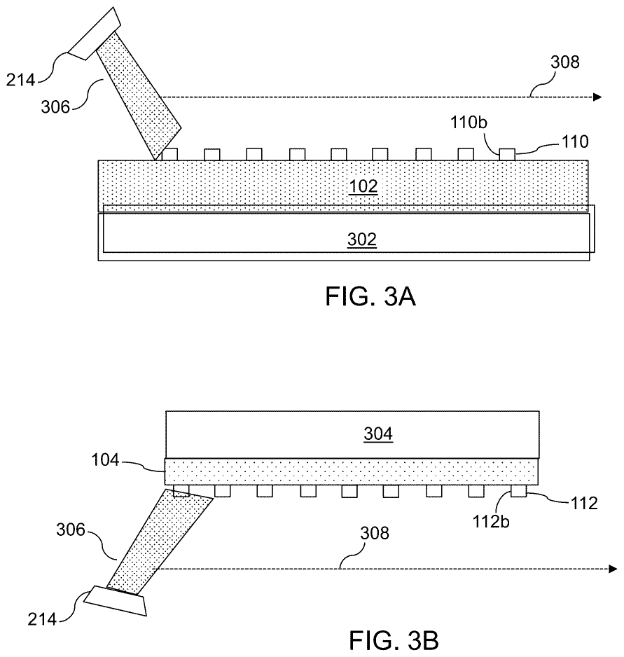

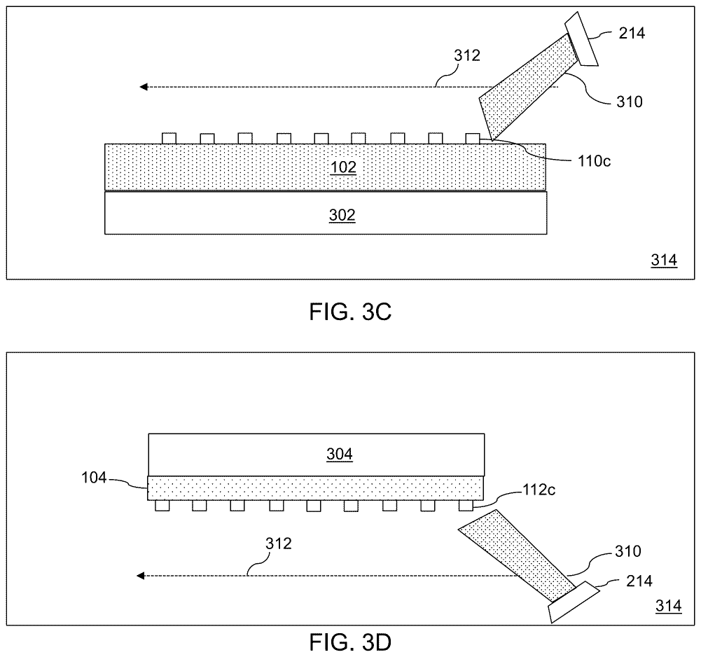

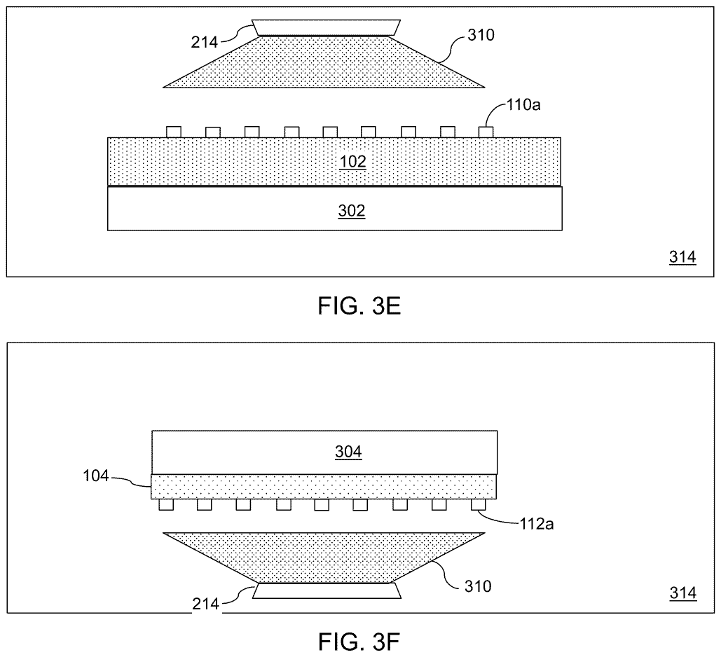

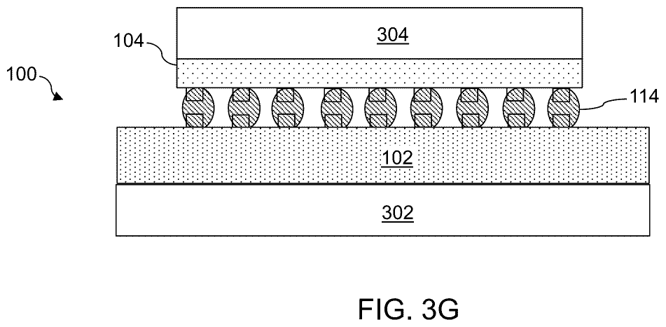

FIG. 3A-3G are vertical cross-sectional views of the semiconductor device 100 during an example process for fabricating the semiconductor device 100 using selective surface treatment.

FIG. 3A illustrates a first step in the process. A plasma nozzle 214 is tilted to an angle with respect to the substrate 102. The substrate 102 is secured to a bond stage 302. An oxidation gas 306 is applied, with the plasma nozzle 214, to a first side 110b of at least one substrate-side copper bump 110, forming an oxidized copper sidewall on the first side 110b of the substrate-side copper bump 110. The oxidation gas 306 may be applied to multiple substrate-side copper bumps 110 by sweeping the plasma nozzle in a horizontal direction 308 from left to right as seen in FIG. 3A.

The oxidation gas 306 used in the process is typically a reactive gas mixture containing oxygen (O₂) or an oxygen-containing compound, such as ozone (O₃) or nitrogen dioxide (NO₂). When applied to the substrate-side copper bumps 110 using a plasma nozzle, the oxidation gas 306 becomes ionized, creating a highly reactive plasma environment that facilitates the oxidation of the copper surface. The plasma nozzle may be precisely oriented to direct the oxidation gas 306 onto the first side 110b of the substrate-side copper bump 110. The ionized oxygen species in the plasma react with the copper atoms on the exposed surface, leading to the formation of a copper oxide layer. This oxidation process may be highly controlled, with parameters such as gas flow rate, nozzle angle, plasma power, and exposure time being optimized to achieve the desired oxide thickness and uniformity on the targeted sidewall.

As the oxidation gas 306 interacts with the first side 110b of the substrate-side copper bump 110, a thin layer of copper oxide (CuO or Cu₂O) may be formed, resulting in an oxidized copper sidewall. This oxide layer may be a few nanometers thick and may act as a passivation layer, protecting the copper surface from further oxidation and contamination. As discussed above, the formation of this oxidized copper sidewall may be useful for controlling the wetting behavior of solder during the subsequent bonding process.

The presence of the oxide layer on the first side 110b of the substrate-side copper bump 110 creates a differential in surface energy between the oxidized and deoxidized sides of the bump 110. This differential may influence the manner, ease, and speed at which the solder 114 spreads and adheres to the copper surface, promoting selective solder wetting on the deoxidized side while preventing excessive spreading or bridging on the oxidized side. The precise control of the oxidation process, including the thickness and composition of the oxide layer, may be useful in achieving the desired soldering characteristics and ensuring the reliability and performance of the semiconductor device 100.

FIG. 3B illustrates that a semiconductor chip 104 may be secured to a bond head 304. A plasma nozzle 214 may be tilted at an angle with respect to the semiconductor chip 104. The plasma nozzle 214 may be the same plasma nozzle used previously or a different plasma nozzle. The oxidation gas 306 may be applied, with the plasma nozzle, to a first side 112b of at least one chip-side copper bump 112, forming an oxidized copper sidewall on the first side 112b of the chip-side copper bump 112. The oxidation gas 306 may be applied to multiple chip-side copper bumps 112 by sweeping the plasma nozzle 214 in the horizontal direction 308 from left to right as illustrated in FIG. 3A.

FIG. 3C illustrates a next step in the process. A plasma nozzle 214 may be tilted to an angle with respect to the substrate 102. A deoxidation gas 310 may applied, with the plasma nozzle, to a second side 110c of the substrate-side copper bump 110, forming a deoxidized copper sidewall on the second side 110c of the substrate-side copper bump 110. The deoxidation gas 310 may be applied to multiple substrate-side copper bumps 110 by sweeping the plasma nozzle 214 in a horizontal direction 312 from right to left, opposite the horizontal direction 308 shown in FIG. 3A. The plasma nozzle 214 may be the same plasma nozzle that directed oxidation gas 306 or may be a separate nozzle.

The deoxidation gas 310 utilized in this process is typically composed of a reducing agent, such as hydrogen (H2) or forming gas (a mixture of hydrogen and nitrogen), which is capable of removing oxide layers from the copper surface. In instances in which the deoxidation gas 310 is applied using a plasma nozzle 214, the deoxidation gas 310 becomes ionized, creating a plasma environment that enhances the chemical reactivity of the deoxidation gas 310. The plasma nozzle 214 may be positioned to direct the deoxidation gas 310 onto the second side 110c of the substrate-side copper bump 110. The ionized hydrogen species interact with the copper oxide that may be present on this side (e.g.,110c), reducing it to metallic copper and effectively stripping away the oxide layer. This reduction process may be controlled by adjusting parameters such as plasma power, gas flow rate, nozzle angle, and exposure time, ensuring that the second side 110c of the copper bump is thoroughly deoxidized without causing any damage to the underlying copper structure.

This deoxidized surface is characterized by its high surface energy and excellent solder wettability, which is useful for the subsequent bonding process. The deoxidized copper sidewall, now clean and oxide-free, provides a pristine surface that promotes uniform solder spreading and adhesion. This selective deoxidation process creates a differential in wetting properties between the first and second sides 110b and 110c of the copper bump, such that the solder preferentially wets the deoxidized side.

FIG. 3D illustrates that the plasma nozzle 214 may be tilted to an angle with respect to the semiconductor chip 104. The plasma nozzle 214 may be the same plasma nozzle used previously or a different plasma nozzle. The deoxidation gas 310 may be applied, with the plasma nozzle 214, to a second side 112c of the chip-side copper bump 112, forming a deoxidized copper sidewall on the second side 112c of the chip-side copper bump 112. The deoxidation gas 310 may be applied to multiple chip-side copper bumps 112 by sweeping the plasma nozzle in the horizontal direction 312. In other embodiments, the plasma nozzle 214 that directs oxidation gas 306 and/or deoxidation gas 310 towards the chip-side copper bumps 112 may be the same or different than the nozzle(s) that direct oxidation gas 306 and/or deoxidation gas 310 towards the substrate-side copper bumps 110.

The application of the deoxidation gas 310 may be performed in an environment 314 with an oxygen concentration of less than 200 parts per million (ppm). The other steps (applying the oxidation gas 306 or the subsequent bonding or both) may also optionally be performed in the low-oxygen environment 314.

This low-oxygen environment 314 is useful for ensuring the effectiveness of the deoxidation process, as even trace amounts of oxygen could react with the copper surface, leading to the reformation of copper oxides during or after the deoxidation treatment. Maintaining such a low oxygen concentration may be performed using specialized equipment, such as inert gas purging systems that continuously displace oxygen with gases like nitrogen or argon. In some embodiments, the process chamber is designed to be hermetically sealed to prevent the ingress of ambient air, which typically contains around 21% oxygen. By reducing the oxygen level to below 200 ppm, the environment 314 effectively minimizes the risk of re-oxidation. As a result, the copper sidewall (110b, 110c, 112b, 112c) remains in a fully deoxidized state, ready for optimal solder wetting during the bonding process.

Referring to FIG. 3E, the plasma nozzle 214 may be tilted to a vertical position with respect to the substrate 102. The deoxidation gas 310 may be applied, with the plasma nozzle 214, to a top surface 110a of the substrate-side copper bump 110, forming a deoxidized surface on the top surface 110a of the substrate-side copper bump 110. The deoxidation gas 310 may be applied to the tops of multiple substrate-side copper bumps 110 by sweeping the plasma nozzle 214 over the substrate-side copper bumps 110 in one of the horizontal directions 308 and 312. The plasma nozzle may be the same plasma nozzle used in FIG. 3A-3D or may be a separate nozzle. For example, the plasma nozzle 214 may be a separate nozzle that is titled to the vertical position.

Once the deoxidation gas 310 is applied against the top surface 110a and the second sidewall surface 110c, the top surface 110a and the second side 110c of the substrate-side copper bump 110 may be deoxidized, while the first side 110b of the substrate-side copper bump 110 remains oxidized. The first side 110b may remain oxidized, even after applying the deoxidation gas 310 towards the top surface 110a, for any of various reasons. For example, the first side 110b may be obstructed from the deoxidation gas 310 by a neighboring bump.

The first side 110b of the substrate-side copper bump 110 may remain oxidized after the application of the deoxidation gas 310 due to several factors that prevent effective exposure to the reducing environment. In some embodiments, one primary reason is the physical obstruction caused by adjacent copper bumps, which can shield the first side 110b from direct contact with the deoxidation gas 310. This obstruction occurs in embodiments in which the bumps are closely spaced, as is common in fine-pitch semiconductor designs, creating a shadowing effect that limits the flow of oxidation gas 306 and/or deoxidation gas 310 to certain sides of the copper bumps.

Additionally, the geometry of the substrate-side copper bump 110 itself, such as a steeper or irregular sidewall angle, may hinder the uniform distribution of the deoxidation gas 310, leaving parts of the surface untreated. The plasma nozzle's orientation and the angle of gas application may also contribute to this selective deoxidation, as the deoxidation gas 310 may be directed predominantly towards the top surface 110a and the second side 110c, with insufficient exposure to the first side 110b. In some embodiments, the configuration of the process may intentionally allow the first side 110b to remain oxidized to achieve differential wetting properties during the soldering process, where the oxidized side is less prone to solder spread, helping to control solder flow and prevent defects such as bridging between adjacent bumps.

FIG. 3F illustrates that the plasma nozzle 214 may be tilted to a vertical position with respect to the semiconductor chip 104 mounted in the bond head 304. The plasma nozzle may be the same plasma nozzle used previously or a different plasma nozzle. The deoxidation gas 310 may be applied, with the plasma nozzle 214, to a top surface 112a of the chip-side copper bump 112, forming a deoxidized surface on the top surface 112a of the chip-side copper bump 112. The deoxidation gas 310 may be applied to the tops of multiple chip-side copper bumps 112 by sweeping the plasma nozzle 214 over the chip-side copper bumps 112 in one of the horizontal directions 308 and 312.

The first side 112b of the chip-side copper bump 112 may remain oxidized after the application of the deoxidation gas 310 due to several factors, i.e., the same factors discussed above with reference to the substrate-side copper bump 110. The configuration of the process may intentionally allow the first side 112b to remain oxidized to achieve differential wetting properties during the soldering process, where the oxidized side is less prone to solder spread, helping to control solder flow and prevent defects such as bridging between adjacent bumps.

FIG. 3G illustrates a bonding step in the process. The semiconductor chip 104 may be bonded to the substrate 102 with electrical and mechanical connections made between the substrate-side copper bumps 110 and the chip-side copper bumps 112 using solder 114.

The bonding process depicted in FIG. 3G typically involves the precise alignment and joining of the semiconductor chip 104 to the substrate 102, facilitated by the electrical and mechanical connections formed between the substrate-side copper bumps 110 and the chip-side copper bumps 112. During this process, the solder 114 establishes a strong metallurgical bond between the opposing substrate-side copper bumps 110 and the chip-side copper bumps 112.

The solder 114 is typically applied to the substrate-side copper bumps 110 and chip-side copper bumps 112 before the bonding step and is in a solid state initially. Once the semiconductor chip 104 and the substrate 102 are aligned, the semiconductor device 100 is subjected to a controlled thermal reflow process, where the temperature is raised above the melting point of the solder 114. In this molten state, the solder 114 flows and wets the deoxidized surfaces of the substrate-side copper bumps 110 and the chip-side copper bumps 112, filling the gaps between them and forming robust intermetallic compounds that secure the connection.

The presence of differentially oxidized sidewalls on the substrate-side copper bumps 110 and the chip-side copper bumps 112 influences the wetting behavior of the solder 114, guiding the solder 114 to the targeted locations and preventing issues like solder bridging or cold joints. After the solder 114 solidifies upon cooling, the solder 114 creates a stable, conductive path between the semiconductor chip 104 and the substrate 102 through the substrate-side copper bumps 110 and the chip-side copper bumps 112. The solder 114 ensures both electrical continuity and mechanical integrity of the bonded structure. The bonding process is typically performed in an inert atmosphere to prevent oxidation of the molten solder, further enhancing the reliability of the interconnects.

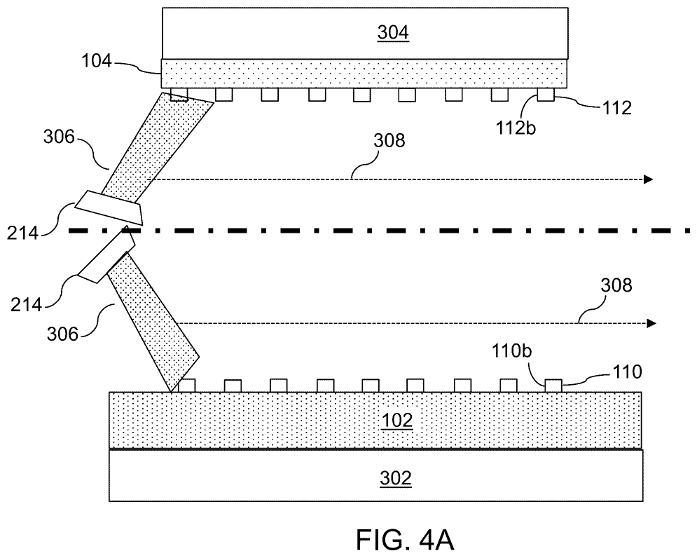

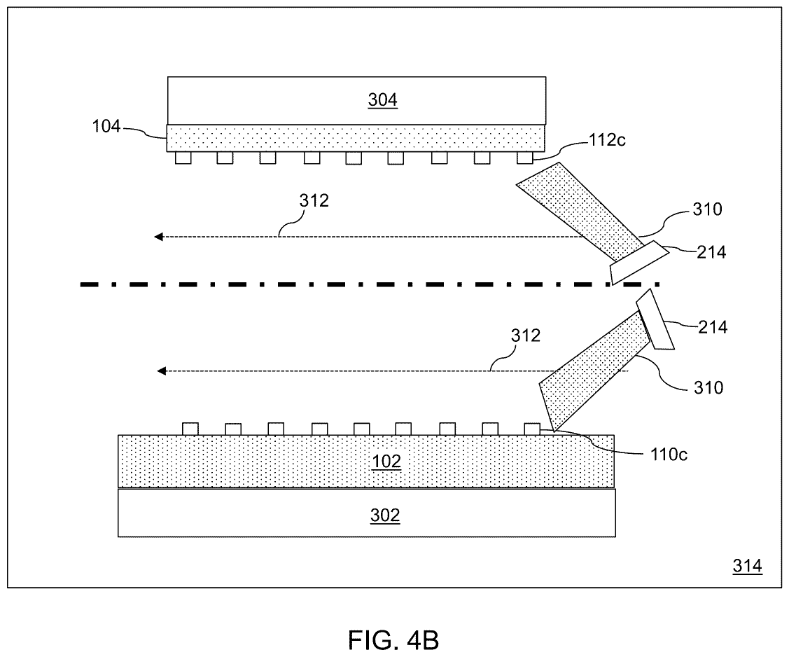

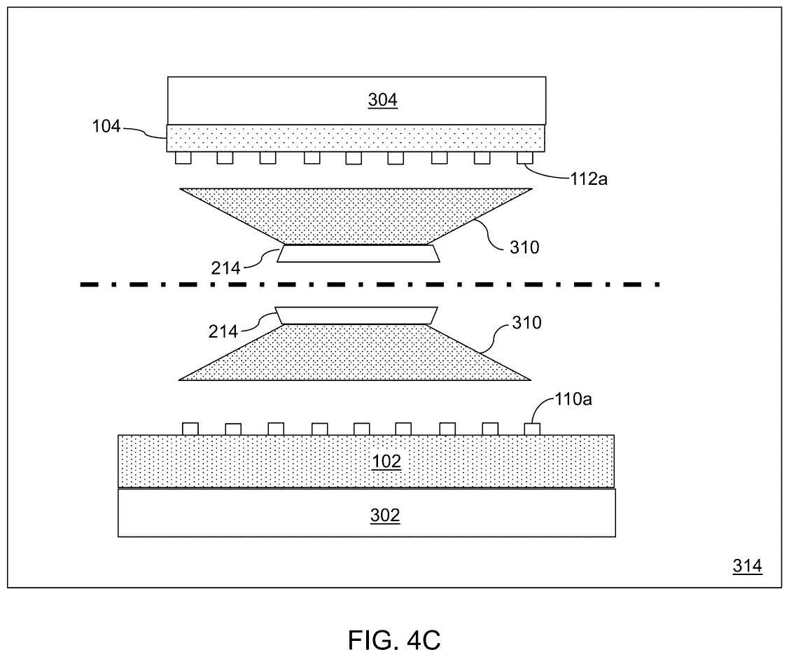

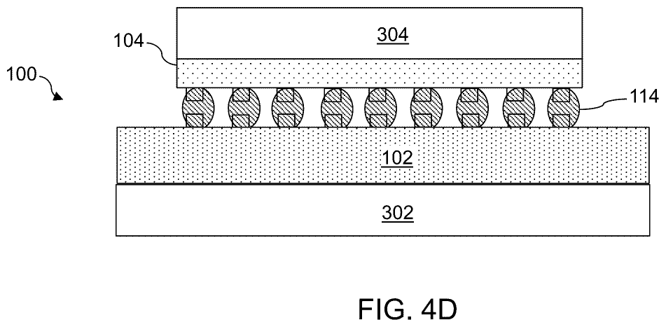

FIGS. 4A-4D are vertical cross-sectional views of the semiconductor device 100 during an example process for fabricating the semiconductor device 100 using selective surface treatment.

FIG. 4A illustrates that the oxidation gas 306 may be applied to the first side 110b of the substrate-side copper bump 110 and the first side 112b of the chip-side copper bump 112 in a configuration with the semiconductor chip 104 and the substrate 102 facing each other in preparation for bonding. The oxidation gas 306 may be applied simultaneously via two different plasma nozzles 214 or the oxidation gas 306 may be applied sequentially using a same plasma nozzle 214 or two different plasma nozzles 214. For example, the oxidation gas 306 may be first applied to the substrate-side copper bump 110 and then to the chip-side copper bump 112, or the oxidation gas 306 may be first applied to the chip-side copper bump 112 and then to the substrate-side copper bump 110.

FIG. 4B illustrates that the deoxidation gas 310 may be applied to the second side 110c of the substrate-side copper bump 110 and the second side 112b of the chip-side copper bump 112 in a configuration with the semiconductor chip 104 and the substrate 102 facing each other. The deoxidation gas 310 may be applied simultaneously by two different plasma nozzles 214 or sequentially by a same plasma nozzle or by two different plasma nozzles 214.

FIG. 4C illustrates that the deoxidation gas 310 may be applied to the top 110a of the substrate-side copper bump 110 and the top 112a of the chip-side copper bump 112 in a configuration with the semiconductor chip 104 and the substrate 102 facing each other. The deoxidation gas 310 may be applied simultaneously by two different plasma nozzles 214 or sequentially by a same plasma nozzle 214 or by two different plasma nozzles 214.

FIG. 4D illustrates a bonding step in the process. The semiconductor chip 104 may be bonded to the substrate 102 with electrical and mechanical connections made between the substrate-side copper bumps 110 and the chip-side copper bumps 112 using solder 114.

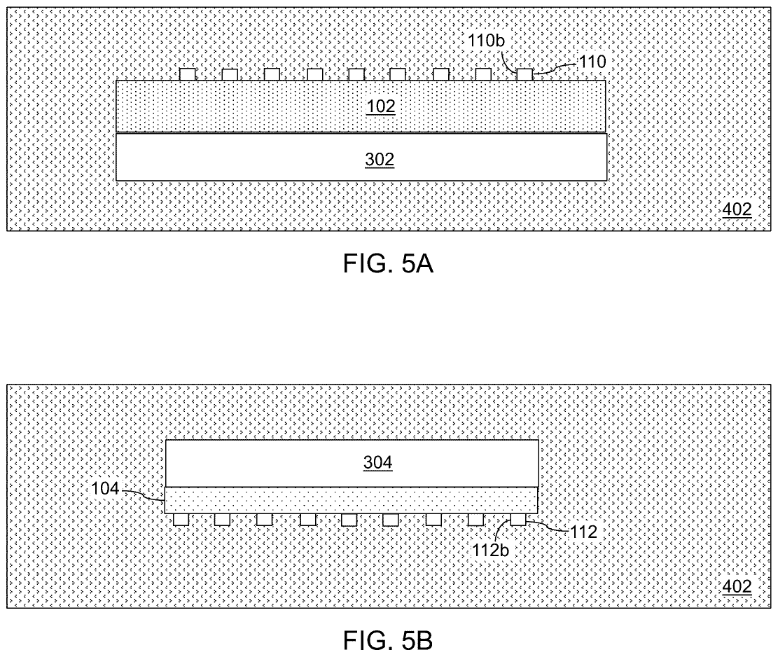

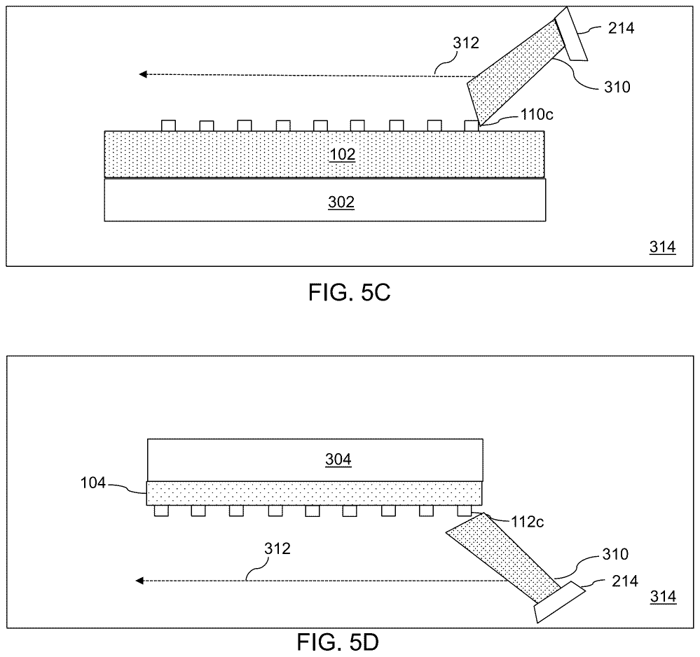

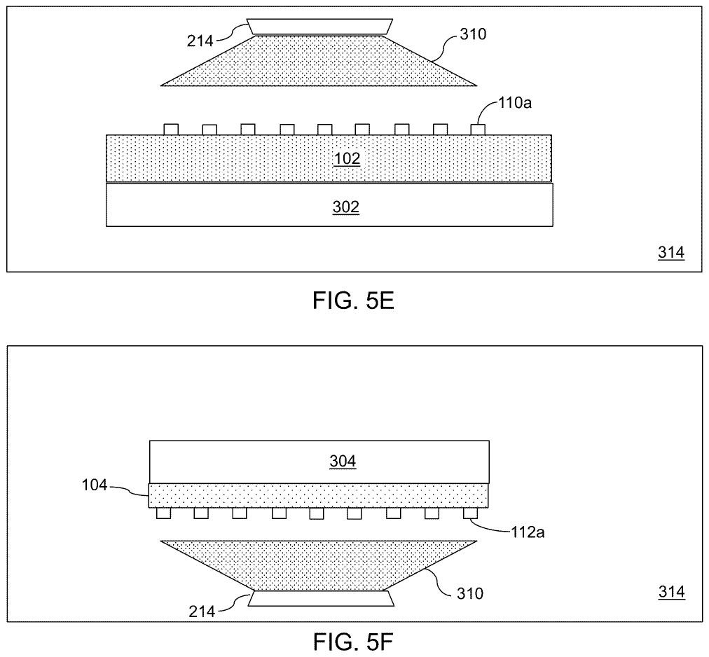

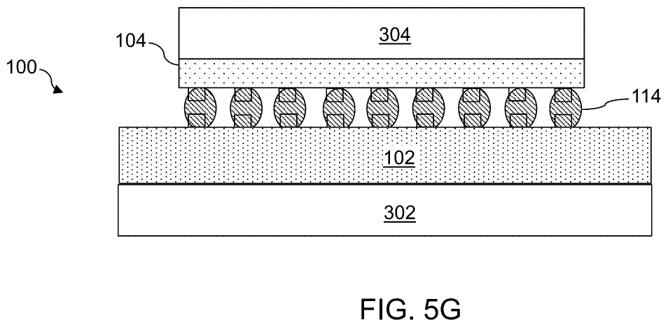

FIG. 5A-5G are vertical cross-sectional views of the semiconductor device 100 during another example process for fabricating the semiconductor device 100 using selective surface treatment.

FIG. 5A illustrates a first step in the process. The substrate 102 is subjected to an oxidation gas plasma chamber 402 treatment, causing the surface of at least one substrate-side copper bump 110 to become oxidized. An oxidized copper sidewall is formed on a first side 110b of the substrate-side copper bump 110 and, in some embodiments, on the other sides 110a, 110c of the substrate-side copper bump 110.

The chamber 402 may be filled with a plasma generated from an oxidation gas, typically consisting of oxygen (O₂) or an oxygen-rich compound like ozone (O₃). The plasma state is achieved by applying an electric field to the gas, ionizing it and creating a highly reactive environment. In embodiments in which the substrate 102 is placed within this chamber 402, the exposed surfaces of the substrate-side copper bump 110, including the first side 110b and the other sides 110a, 110c, are subjected to this reactive plasma. The ionized oxygen species interact with the copper atoms on the bump's surface, initiating an oxidation reaction that forms a thin layer of copper oxide (CuO or Cu₂O) on exposed surfaces.

The oxidized copper sidewall may be specifically formed on the first side 110b, as well as on the remaining sides of the substrate-side copper bump 110, as the plasma treatment uniformly affects exposed areas of the bump. The thickness and uniformity of the oxide layer may be controlled by adjusting parameters such as the plasma power, exposure duration, gas flow rate, and chamber pressure. The oxide layer may serve as a passivation barrier, preventing further oxidation or contamination of the copper surface while also differentiating the surface energy across the substrate-side copper bump 110.

FIG. 5B illustrates that the semiconductor chip 104 may be subjected to an oxidation gas plasma chamber 402 treatment, causing the surface of at least one chip-side copper bump 112 to become oxidized. An oxidized copper sidewall is formed on a first side 112b of the chip-side copper bump 112 and, in some embodiments, on the other sides 112a, 112c of the chip-side copper bump 112. In some embodiments, the semiconductor chip 104 may be subjected to the oxidation gas plasma chamber 402 treatment simultaneously with the substrate 102.

FIG. 5C illustrates a next step in the process. A plasma nozzle 214 may be tilted to an angle with respect to the substrate 102. A deoxidation gas 310 is applied, with the plasma nozzle, to a second side 110c of the substrate-side copper bump 110, forming a deoxidized copper sidewall on the second side 110c of the substrate-side copper bump 110. The deoxidation gas 310 may be applied to multiple substrate-side copper bumps 110 by sweeping the plasma nozzle in a horizontal direction 312 from right to left.

Referring to FIG. 5D, the plasma nozzle 214 may be tilted to an angle with respect to the semiconductor chip 104. The plasma nozzle 214 may be the same plasma nozzle used previously or a different plasma nozzle. The deoxidation gas 310 may be applied, with the plasma nozzle 214, to a second side 112c of the chip-side copper bump 112, forming a deoxidized copper sidewall on the second side 112c of the chip-side copper bump 112. The deoxidation gas 310 may be applied to multiple chip-side copper bumps 112 by sweeping the plasma nozzle in a horizontal direction 312 from right to left.

Referring to FIG. 5E the plasma nozzle 214 may be tilted to a vertical position with respect to the substrate 102. The plasma nozzle 214 may be the same plasma nozzle used previously or a different plasma nozzle. The deoxidation gas 310 is applied, with the plasma nozzle 214, to a top surface 110a of the substrate-side copper bump 110, forming a deoxidized surface on the top surface 110a of the substrate-side copper bump 110. The deoxidation gas 310 may be applied to the tops of multiple substrate-side copper bumps 110 by sweeping the plasma nozzle 214 over the substrate-side copper bumps 110 in one of the horizontal directions 308 and 312.

After this step is complete, the top surface 110a and the second side 110c of the substrate-side copper bump 110 are deoxidized, while the first side 110b of the substrate-side copper bump 110 remains oxidized. The top surface 110a and the second side 110c of the substrate-side copper bump 110 are deoxidized even though oxidized surfaces may have initially formed during the oxidation gas plasma chamber 402 treatment.

Referring to FIG. 5F, the plasma nozzle 214 may be tilted to a vertical position with respect to the semiconductor chip 104. The plasma nozzle 214 may be the same plasma nozzle used previously or a different plasma nozzle. The deoxidation gas 310 is applied, with the plasma nozzle 214, to a top surface 112a of the chip-side copper bump 112, forming a deoxidized surface on the top surface 112a of the chip-side copper bump 112. The deoxidation gas 310 may be applied to the tops of multiple chip-side copper bumps 112 by sweeping the plasma nozzle 214 over the chip-side copper bumps 112 in one of the horizontal directions 308 and 312. The top surface 112a and the second side 112c of the chip-side copper bump 112 are deoxidized, while the first side 112b of the chip-side copper bump 112 remains oxidized.

FIG. 5G illustrates a bonding step in the process. The semiconductor chip 104 is bonded to the substrate 102 with electrical and mechanical connections made between the substrate-side copper bumps 110 and the chip-side copper bumps 112 using solder 114. The presence of differentially oxidized sidewalls on the substrate-side copper bump 110 and the chip-side copper bump 112 influences the wetting behavior of the solder 114, guiding the solder 114 to the targeted locations and preventing issues like solder bridging or cold joints.

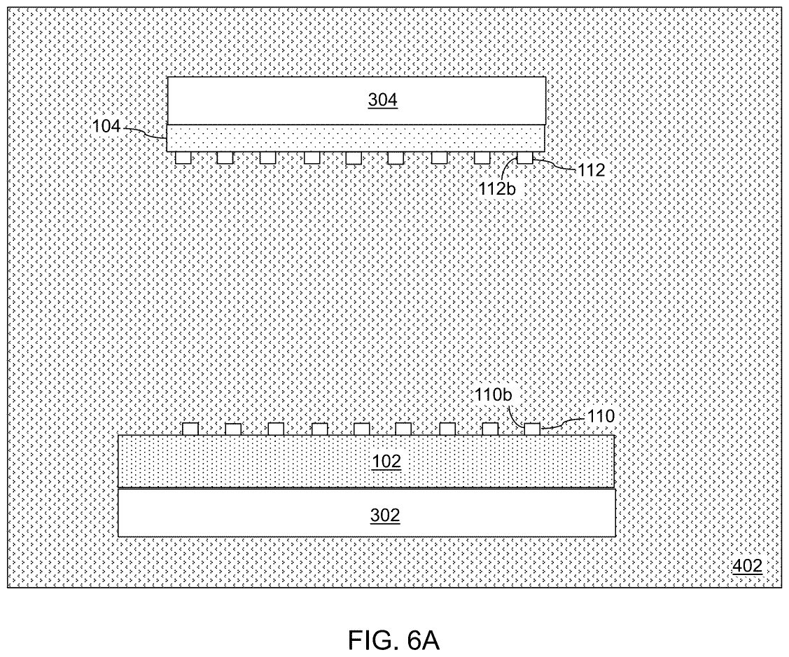

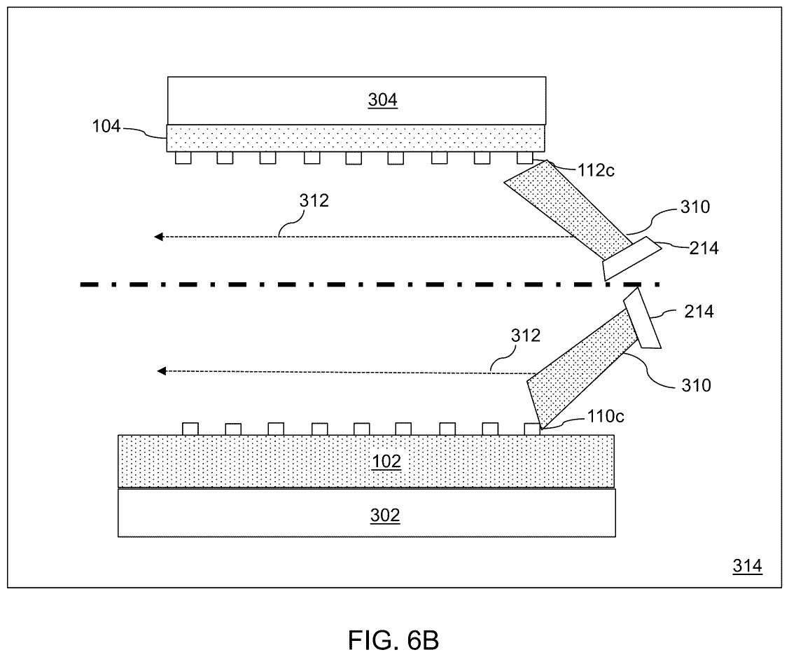

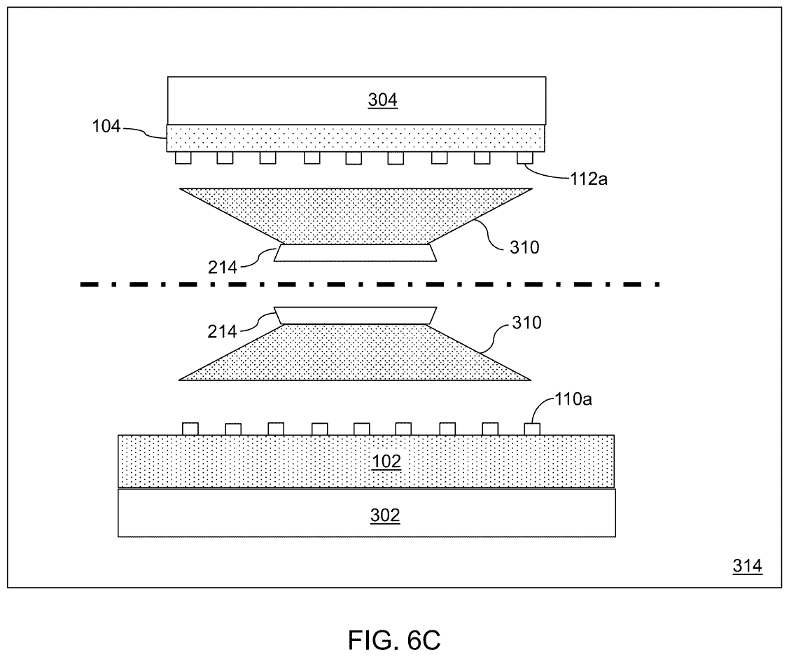

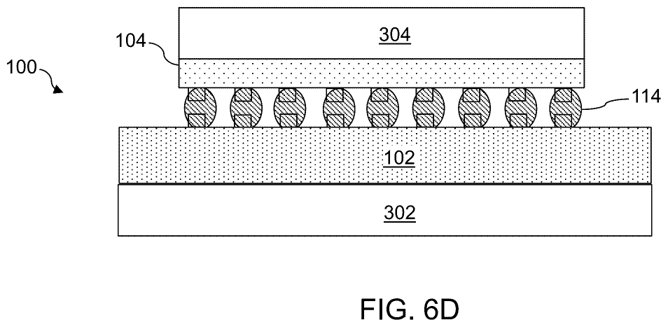

FIGS. 6A-6D are vertical cross-sectional view of the semiconductor device 100 during an example process for fabricating the semiconductor device 100 using selective surface treatment.

FIG. 6A illustrates that oxidation gas plasma chamber 402 treatment may be applied to the first side 110b of the substrate-side copper bump 110 and the first side 112b of the chip-side copper bump 112 simultaneously. In some embodiments, the oxidation gas plasma chamber 402 treatment is applied in a configuration with the semiconductor chip 104 and the substrate 102 facing each other in preparation for bonding.

FIG. 6B illustrates that the deoxidation gas 310 may be applied to the second side 110c of the substrate-side copper bump 110 and the second side 112b of the chip-side copper bump 112 in a configuration with the semiconductor chip 104 and the substrate 102 facing each other. The deoxidation gas 310 may be applied simultaneously by two different plasma nozzles 214 or sequentially by a same plasma nozzle or by two different plasma nozzles.

FIG. 6C illustrates that the deoxidation gas 310 may be applied to the top 110a of the substrate-side copper bump 110 and the top 112a of the chip-side copper bump 112 in a configuration with the semiconductor chip 104 and the substrate 102 facing each other. The deoxidation gas 310 may be applied simultaneously by two different plasma nozzles 214 or sequentially by a same plasma nozzle or by two different plasma nozzles.

FIG. 6D illustrates a bonding step in the process. The semiconductor chip 104 may be bonded to the substrate 102 with electrical and mechanical connections made between the substrate-side copper bumps 110 and the chip-side copper bumps 112 using solder 114.

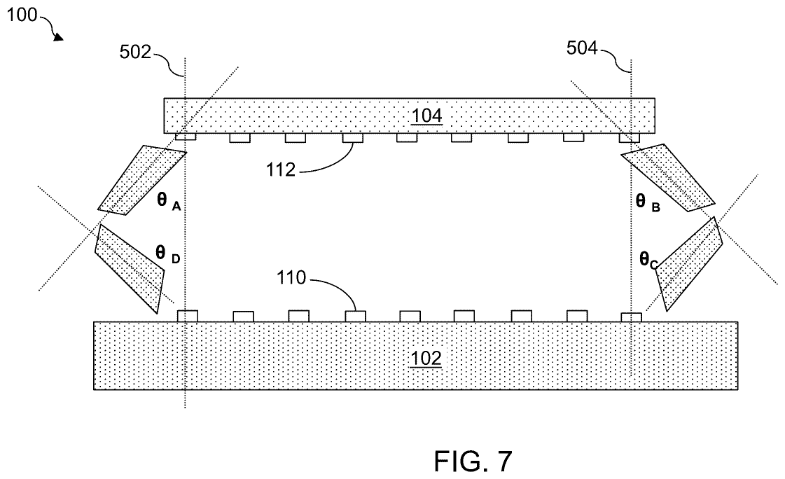

FIG. 7 is a vertical cross-sectional view of the semiconductor device 100 that illustrates various angles at which a plasma nozzle 214 may be directed for selective surface treatment of substrate-side copper bump 110 and the chip-side copper bump 112. In some embodiments, the plasma nozzle is positioned by rotating the nozzle angle. In some embodiments, one or more additional plasma nozzles are installed to achieve different angles or for the application of oxidization gas and deoxidation gas. The plasma nozzles 214 may be configured to rotate and tilt, allowing precise control over the direction and focus of the oxidation and deoxidation gases.

FIG. 7 shows four different plasma tilt angles with respect to vertical axes 502 and 504 that are perpendicular to the substrate 102 and semiconductor chip 104: θ_{A}, for application of gas to a first side of the chip-side copper bumps 112; θ_{B}, for application of gas to a second side of the chip-side copper bumps 112; θ_{C}, for application of gas to a second side of the substrate-side copper bumps 110; and θ_{D}, for application of gas to a first side of the substrate-side copper bumps 110. In some embodiments, the plasma tilt angles are between 30° and 75°, i.e., such that 30°<θ_{A}, θ_{B}, θ_{C}, θ_{D} <75°. In some embodiments, the plasma tilt angles are between 45° and 60°, i.e., such that 45°<θ_{A}, θ_{B}, θ_{C}, θ_{D}<60°.

In general, the plasma tilt angles θ_{A}, θ_{B} for the semiconductor chip 104 are mirrored but opposite to the plasma tilt angles θ_{C}, θ_{D} for the substrate 102. For example, θ_{A}<0, θ_{B}>0, θ_{C}<0, θ_{D}>0. This arrangement of plasma tilt angles may result in similar selective surface treatment for the chip-side copper bumps 112 and the substrate-side copper bumps 110.

Selecting an appropriate plasma tilt angle for a given application may involve consideration of several factors, including the geometry of the copper bumps, the desired surface treatment outcome, and the specific requirements of the bonding process. The tilt angle may determine the plasma's area of impact on the bump surface, thereby influencing the uniformity and effectiveness of the oxidation or deoxidation process. For instance, in applications where the goal is to oxidize only one side of a copper bump while leaving the other sides relatively untouched, a shallower tilt angle, such as 30 to 45 degrees, may be chosen. This angle ensures that the plasma primarily contacts the targeted sidewall, creating a well-defined oxidized layer without excessive exposure to the other sides.

The selection process may include an analysis of the bump's dimensions, including its height, width, and sidewall angles. The plasma's spread and intensity at different angles may be simulated or experimentally tested to determine suitable conditions for the desired surface modification. For example, in instances in which the goal is to create a deoxidized sidewall on a specific side of the bump while ensuring that other sides remain oxidized or unaffected, a steeper tilt angle, such as 60 to 75 degrees, may be required. This angle directs the plasma more perpendicularly to the targeted side, maximizing the deoxidation effect while minimizing the exposure of other areas.

Additionally, selection of a plasma tilt angle may include consideration of the proximity of adjacent bumps, as closely spaced bumps can create shadowing effects that obstruct the plasma from reaching certain areas. In such cases, the tilt angle may be adjusted to account for these obstructions, or additional nozzles may be deployed to ensure complete coverage.

In some embodiments, the selected plasma tilt angle is refined through iterative testing, where the resulting surface characteristics are evaluated using techniques like scanning electron microscopy (SEM) or energy-dispersive X-ray spectroscopy (EDX) to confirm that the desired oxide thickness and surface condition are achieved. The chosen plasma tilt angle may strike a balance between achieving precise surface treatment and maintaining the overall efficiency and effectiveness of the semiconductor manufacturing process.

The following discussion now refers to a number of methods and method steps. Although the method steps are discussed in specific orders or are illustrated in a flow chart as being performed in a particular order, no order is required unless expressly stated or required because a step is dependent on another step being completed prior to the step being performed.

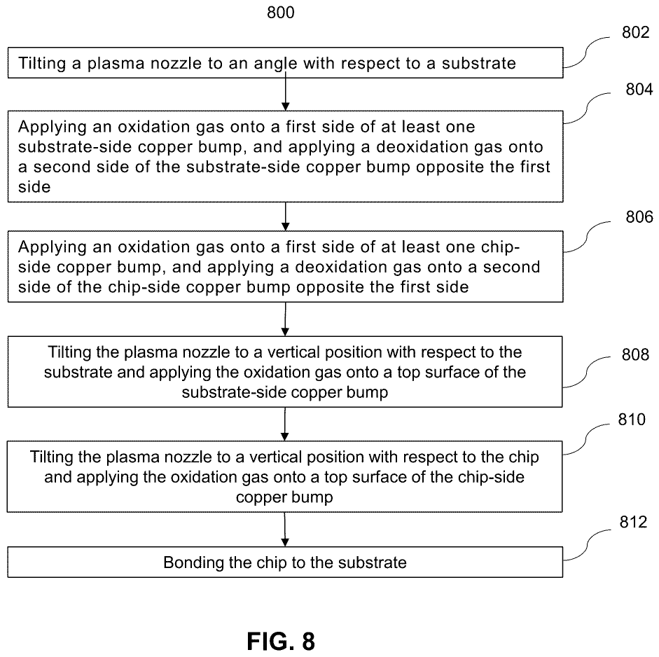

Embodiments are now described in connection with FIG. 8, which illustrates a flow diagram of an example method 800 for fabricating a semiconductor device 100 according to some embodiments of the present disclosure.

In an embodiment method 800, step 802 comprises tilting a plasma nozzle 214 to an angle with respect to a substrate 102. In an embodiment method 800, step 804 comprises applying, with the plasma nozzle 214, an oxidation gas 306 onto a first side 110b of at least one substrate-side copper bump 110 on the substrate 102, forming an oxidized copper sidewall on the first side 110b of the substrate-side copper bump 110. In an embodiment method 800, step 804 comprises applying, with the plasma nozzle 214, a deoxidation gas 310 onto a second side 110c of the substrate-side copper bump 110 opposite the first side 110b of the substrate-side copper bump 110, forming a deoxidized copper sidewall on the second side 110c of the substrate-side copper bump 110.

In an embodiment method 800, step 806 comprises applying, with the plasma nozzle 214, an oxidation gas 306 onto a first side 112b of at least one chip-side copper bump 112 on a semiconductor chip 104, forming an oxidized copper sidewall on the first side 112b of the chip-side copper bump 112. In an embodiment method 800, step 806 comprises applying, with the plasma nozzle 214, a deoxidation gas 310 onto a second side 112c of the chip-side copper bump 112 opposite the first side 112b of the chip-side copper bump 112, forming a deoxidized copper sidewall on the second side 112c of the chip-side copper bump 112.

In an embodiment method 800, step 808 comprises tilting the plasma nozzle 214 to a vertical position with respect to the substrate 102 and applying the deoxidation gas 306 onto a top surface 110a of the substrate-side copper bump 110. In an embodiment method 800, step 810 comprises tilting the plasma nozzle 214 to a vertical position with respect to the semiconductor chip 104 and applying the deoxidation gas 306 onto a top surface 112a of the chip-side copper bump 112.

In an embodiment method 800, step 812 comprises bonding the semiconductor chip 104 to the substrate 102 using the substrate-side copper bump 110 and the chip-side copper bump 112. The chip-side copper bump 112 may be aligned opposite to the substrate-side copper bump 110 in a vertical direction, and bonding the semiconductor chip to the substrate comprises reflowing a solder material between the deoxidized copper sidewall and the top surface 110a of the substrate-side copper bump 110 and the corresponding deoxidized copper sidewall and top surface 112a of the chip-side copper bump 112, forming a metallurgical bond between the semiconductor chip 104 and the substrate 102. Bonding the semiconductor chip 104 to the substrate 102 may include applying a layer of solder 114 to the deoxidized copper sidewall and a top surface 110a of the substrate-side copper bump 110 and reflowing the solder 114 to form an electrical and mechanical connection between the semiconductor chip 104 and the substrate 102. Reflowing the solder 114 may be conducted under a controlled atmosphere to prevent reoxidation of the deoxidized copper sidewall and to cause uniform solder wetting across the top surface 110a and the deoxidized copper sidewall of the substrate-side copper bump 110.

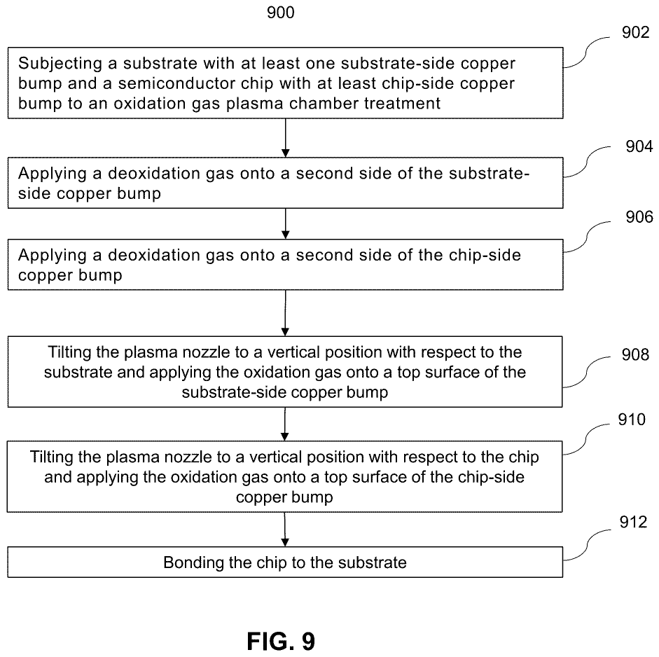

Embodiments are now described in connection with FIG. 9, which illustrates a flow diagram of an example method 900 for fabricating a semiconductor device 100 according to some embodiments of the present disclosure.

In an embodiment method 900, step 902 comprises subjecting a substrate 102 with at least one substrate-side copper bump 110 to an oxidation gas plasma chamber 402 treatment, forming an oxidized copper sidewall on a first side 110b of the substrate-side copper bump 110. In an embodiment method 900, step 902 comprises subjecting a semiconductor chip 104 with at least one chip-side copper bump 112 to the oxidation gas plasma chamber 402 treatment, forming an oxidized copper sidewall on a first side 112b of the chip-side copper bump 112.

In an embodiment method 900, step 904 comprises applying a deoxidation 310 gas onto a second side 110c of the substrate-side copper bump 110 opposite the first side 110b of the substrate-side copper bump 110, forming a deoxidized copper sidewall on the second side 110c of the substrate-side copper bump 110. In an embodiment method 900, step 906 comprises applying a deoxidation 310 gas onto a second side 112c of the chip-side copper bump 112 opposite the first side 112b of the chip-side copper bump 112, forming a deoxidized copper sidewall on the second side 112c of the chip-side copper bump 112.

In an embodiment method 900, step 908 comprises tilting the plasma nozzle 214 to a vertical position with respect to the substrate 102 and applying the deoxidation gas 306 onto a top surface 110a of the substrate-side copper bump 110. In an embodiment method 900, step 910 comprises tilting the plasma nozzle 214 to a vertical position with respect to the semiconductor chip 104 and applying the deoxidation gas 306 onto a top surface 112a of the chip-side copper bump 112.

In an embodiment method 900, step 912 comprises bonding the semiconductor chip 104 to the substrate 102 using the substrate-side copper bump 110 and the chip-side copper bump 112. The chip-side copper bump 112 may be aligned opposite to the substrate-side copper bump 110 in a vertical direction, and bonding the semiconductor chip to the substrate comprises reflowing a solder material between the deoxidized copper sidewall and the top surface 110a of the substrate-side copper bump 110 and the corresponding deoxidized copper sidewall and top surface 112a of the chip-side copper bump 112, forming a metallurgical bond between the semiconductor chip 104 and the substrate 102. Bonding the semiconductor chip 104 to the substrate 102 may include applying a layer of solder 114 to the deoxidized copper sidewall and a top surface 110a of the substrate-side copper bump 110 and reflowing the solder 114 to form an electrical and mechanical connection between the semiconductor chip 104 and the substrate 102. Reflowing the solder 114 may be conducted under a controlled atmosphere to prevent reoxidation of the deoxidized copper sidewall and to cause uniform solder wetting across the top surface 110a and the deoxidized copper sidewall of the substrate-side copper bump 110.

The various embodiments disclosed herein may provide various advantages and improvements. Asymmetric wetting of the copper bumps 110, 112 results from selective surface treatment of the copper bumps 110, 112. The asymmetric wetting can reduce the incidence of cold joints and solder bridge defects. In some embodiments, wetting is avoided on a deoxidized side of copper bumps in 95% or more of the copper bumps, which may be useful in applications with large package sizes and small pitches.

Referring to all drawings and according to various embodiments of the present disclosure, a method for manufacturing a semiconductor device is provided. The method including: tilting a plasma nozzle 214 to an angle with respect to a substrate 102; applying, with the plasma nozzle 214, an oxidation gas 306 onto a first side 110b at least one substrate-side copper bump 110 on the substrate 102, forming an oxidized copper sidewall on the first side 110b of the substrate-side copper bump 110; and bonding a semiconductor chip 104 to the substrate 102 using the substrate-side copper bump 110.

In one embodiment, the method may further include: applying, with the plasma nozzle 214, a deoxidation gas 310 onto a second side 110c of the substrate-side copper bump 110 opposite the first side 110b of the substrate-side copper bump 110, forming a deoxidized copper sidewall on the second side 110c of the substrate-side copper bump 110; and tilting the plasma nozzle 214 to a vertical position with respect to the substrate 110 and applying the deoxidation gas 310 onto a top surface 110a of the substrate-side copper bump 110. In one embodiment, the method may further include: applying, with the plasma nozzle 214, the oxidation gas 306 onto a first side 112b of at least one chip-side copper bump 112 on the semiconductor chip 104, forming an oxidized copper sidewall on the first side 112b of the chip-side copper bump 112; and applying, with the plasma nozzle 214, a deoxidation gas 310 onto a second side 112c of the chip-side copper bump 112 opposite the first side 112b of the chip-side copper bump 112, forming a deoxidized copper sidewall on the second side 112c of the chip-side copper bump 112. In one embodiment, the chip-side copper bump 112 may be aligned opposite to the substrate-side copper bump 110, and wherein bonding the semiconductor chip 104 to the substrate 102 comprises reflowing a solder material 114 between the deoxidized copper sidewall and the top surface 110a of the substrate-side copper bump 110 and the corresponding deoxidized copper sidewall and top surface 112a of the chip-side copper bump 112, forming a metallurgical bond between the semiconductor chip 104 and the substrate 102. In one embodiment, bonding the semiconductor chip 104 to the substrate 102 comprises applying a layer of solder 114 to the deoxidized copper sidewall and a top surface 110a of the substrate-side copper bump and reflowing the solder 114 to form an electrical and mechanical connection between the semiconductor chip 104 and the substrate 102. In one embodiment, reflowing the solder 114 is conducted under a controlled atmosphere to prevent reoxidation of the deoxidized copper sidewall and to cause uniform solder wetting across the top surface 110a and the deoxidized copper sidewall of the substrate-side copper bump 110.

In one embodiment, the method may further include placing the substrate 102 and the semiconductor chip 104 in an environment 314 with an oxygen concentration of less than 200 parts per million (ppm), wherein applying the deoxidation gas 310 and bonding the semiconductor chip 104 to the substrate 102 occurs in the environment 314. In one embodiment, the plasma nozzle 214 is tilted at an angle between 30 and 75 degrees with respect to the substrate 102 during the application of the oxidation gas 306 and the deoxidation gas 310.

In another aspect of the embodiments, and with reference to all drawings, a method for manufacturing a semiconductor device is provided, the method comprising: subjecting a substrate 102 with at least one substrate-side copper bump 110 to an oxidation gas plasma chamber treatment 402, forming an oxidized copper sidewall on a first side 110b of the substrate-side copper bump 110; and bonding a semiconductor chip 104 to the substrate 102 using the substrate-side copper bump 110.

In one embodiment, the method may further include: tilting a plasma nozzle 214 to an angle with respect to the substrate 102 and applying, with the plasma nozzle 214, a deoxidation gas 310 onto a second side 110c of the substrate-side copper bump 110 opposite the first side 110b, forming a deoxidized copper sidewall on the second side 110c of the substrate-side copper bump 110; and applying a vertical plasma spray of deoxidation gas 310 onto a top surface 110a of the substrate-side copper bump 110, deoxidizing the top surface of the substrate-side copper bump 110. In one embodiment, the method includes: forming an oxidized copper sidewall on a first side 112b of a chip-side copper bump 112 by subjecting the semiconductor chip 104 to the oxidation gas plasma chamber treatment 402; and forming a deoxidized copper sidewall on the second side 112c of the chip-side copper bump 112 by applying, with the plasma nozzle 214, a deoxidation gas 310 onto a second side 112c of the chip-side copper bump 112 opposite the first side 112b of the chip-side copper bump 112. In one embodiment, the chip-side copper bump 112 may be aligned opposite to the substrate-side copper bump 110, and wherein bonding the semiconductor chip 104 to the substrate 102 comprises reflowing a solder material 114 between the deoxidized copper sidewall and the top surface 110a of the substrate-side copper bump 110 and the corresponding deoxidized copper sidewall and top surface 112a of the chip-side copper bump 112, forming a metallurgical bond between the semiconductor chip 104 and the substrate 102. In one embodiment, bonding the semiconductor chip 104 to the substrate 102 comprises: applying a layer of solder 114 to the deoxidized copper sidewall and a top surface 110a of the substrate-side copper bump 110; and reflowing the solder 114 to form an electrical and mechanical connection between the semiconductor chip 104 and the substrate 102. In one embodiment, reflowing the solder 114 may be conducted under a controlled atmosphere to prevent reoxidation of the deoxidized copper sidewall and to cause uniform solder wetting across the top surface and the deoxidized copper sidewall of the substrate-side copper bump 110. In one embodiment, applying the deoxidation gas 310 and bonding the semiconductor chip 104 to the substrate 102 are carried out in an environment with an oxygen concentration of less than 200 parts per million (ppm). In one embodiment, the plasma nozzle 214 is tilted at an angle between 30 and 75 degrees with respect to the substrate 102 during the application of the oxidation gas 306 and the deoxidation gas 310.

In another aspect of the embodiments, and with reference to all drawings, semiconductor device 100 is provided, the semiconductor device 100 may include: a substrate comprising at least one substrate-side copper bump, the substrate-side copper bump including: an oxidized copper sidewall on a first side 110b of the substrate-side copper bump 110; a deoxidized copper sidewall on a second side 110c of the substrate-side copper bump 110, opposite the first side 110b; and a deoxidized top surface 110a of the substrate-side copper bump 110; a semiconductor chip 104 bonded to the substrate 102, wherein the semiconductor chip 104 includes at least one chip-side copper bump 112 aligned opposite the substrate-side copper bump 110.

In one embodiment, the chip-side copper bump 112 comprises: an oxidized copper sidewall on a first side 112b of the chip-side copper bump 112; a deoxidized copper sidewall on a second side 112c of the chip-side copper bump 112, opposite the first side 112b; and a deoxidized top surface 112a of the chip-side copper bump 112, wherein the deoxidized copper sidewall and top surface 112a of the chip-side copper bump 112 are aligned with the corresponding deoxidized copper sidewall and top surface 110a of the substrate-side copper bump 110. In one embodiment, the bonding between the substrate-side copper bump 110 and the chip-side copper bump 112 is formed by reflowed solder material 114, creating an electrical and mechanical connection between the semiconductor chip 104 and the substrate 102. In one embodiment, the oxidized copper sidewall on the substrate-side copper bump 110 has an oxide layer with a thickness of A nanometers, and the deoxidized copper sidewall on the substrate-side copper bump 110 has an oxide layer with a thickness of B nanometers, wherein the difference in oxide thickness, A minus B, is at least 3 nanometers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, the method comprising:
tilting a plasma nozzle to an angle with respect to a substrate;
applying, with the plasma nozzle, an oxidation gas onto a first side of at least one substrate-side copper bump on the substrate, forming an oxidized copper sidewall on the first side of the substrate-side copper bump; and
bonding a semiconductor chip to the substrate using the substrate-side copper bump.

2. The method of claim 1, comprising:
applying, with the plasma nozzle, a deoxidation gas onto a second side of the substrate-side copper bump opposite the first side of the substrate-side copper bump, forming a deoxidized copper sidewall on the second side of the substrate-side copper bump; and
tilting the plasma nozzle to a vertical position with respect to the substrate and applying the deoxidation gas onto a top surface of the substrate-side copper bump.

3. The method of claim 1, comprising:
applying, with the plasma nozzle, the oxidation gas onto a first side of at least one chip-side copper bump on the semiconductor chip, forming an oxidized copper sidewall on the first side of the chip-side copper bump; and
applying, with the plasma nozzle, a deoxidation gas onto a second side of the chip-side copper bump opposite the first side of the chip-side copper bump, forming a deoxidized copper sidewall on the second side of the chip-side copper bump.

4. The method of claim 3, wherein the chip-side copper bump is aligned opposite to the substrate-side copper bump, and wherein bonding the semiconductor chip to the substrate comprises reflowing a solder material between the deoxidized copper sidewall and the top surface of the substrate-side copper bump and the corresponding deoxidized copper sidewall and top surface of the chip-side copper bump, forming a metallurgical bond between the semiconductor chip and the substrate.

5. The method of claim 1, wherein bonding the semiconductor chip to the substrate comprises applying a layer of solder to the deoxidized copper sidewall and a top surface of the substrate-side copper bump and reflowing the solder to form an electrical and mechanical connection between the semiconductor chip and the substrate.

6. The method of claim 5, wherein reflowing the solder is conducted under a controlled atmosphere to prevent reoxidation of the deoxidized copper sidewall and to cause uniform solder wetting across the top surface and the deoxidized copper sidewall of the substrate-side copper bump.

7. The method of claim 2, comprising placing the substrate and the semiconductor chip in an environment with an oxygen concentration of less than 200 parts per million (ppm), wherein applying the deoxidation gas and bonding the semiconductor chip to the substrate occurs in the environment.

8. The method of claim 2, wherein the plasma nozzle is tilted at an angle between 30 and 75 degrees with respect to the substrate during an application of the oxidation gas and the deoxidation gas.

9. A method for manufacturing a semiconductor device, the method comprising:
subjecting a substrate with at least one substrate-side copper bump to an oxidation gas plasma chamber treatment, forming an oxidized copper sidewall on a first side of the substrate-side copper bump; and
bonding a semiconductor chip to the substrate using the substrate-side copper bump.

10. The method of claim 9, comprising:
tilting a plasma nozzle to an angle with respect to the substrate and applying, with the plasma nozzle, a deoxidation gas onto a second side of the substrate-side copper bump opposite the first side, forming a deoxidized copper sidewall on the second side of the substrate-side copper bump; and
applying a vertical plasma spray of deoxidation gas onto a top surface of the substrate-side copper bump, deoxidizing the top surface of the substrate-side copper bump.

11. The method of claim 9, comprising:
forming an oxidized copper sidewall on a first side of a chip-side copper bump by subjecting the semiconductor chip to the oxidation gas plasma chamber treatment; and
forming a deoxidized copper sidewall on the second side of the chip-side copper bump by applying, with a plasma nozzle, a deoxidation gas onto a second side of the chip-side copper bump opposite the first side of the chip-side copper bump.

12. The method of claim 11, wherein the chip-side copper bump is aligned opposite to the substrate-side copper bump, and wherein bonding the semiconductor chip to the substrate comprises reflowing a solder material between the deoxidized copper sidewall and the top surface of the substrate-side copper bump and the corresponding deoxidized copper sidewall and top surface of the chip-side copper bump, forming a metallurgical bond between the semiconductor chip and the substrate.

13. The method of claim 9, wherein bonding the semiconductor chip to the substrate comprises:
applying a layer of a solder material to the deoxidized copper sidewall and a top surface of the substrate-side copper bump; and
reflowing the solder material to form an electrical and mechanical connection between the semiconductor chip and the substrate.

14. The method of claim 13, wherein reflowing the solder is conducted under a controlled atmosphere to prevent reoxidation of the deoxidized copper sidewall and to cause uniform solder wetting across the top surface and the deoxidized copper sidewall of the substrate-side copper bump.

15. The method of claim 9, wherein applying the deoxidation gas and bonding the semiconductor chip to the substrate are carried out in an environment with an oxygen concentration of less than 200 parts per million (ppm).

16. The method of claim 9, wherein the plasma nozzle is tilted at an angle between 30 and 75 degrees with respect to the substrate during the application of the oxidation gas and the deoxidation gas.

17. A semiconductor device comprising:
a substrate comprising at least one substrate-side copper bump, the substrate-side copper bump including:
an oxidized copper sidewall on a first side of the substrate-side copper bump;
a deoxidized copper sidewall on a second side of the substrate-side copper bump, opposite the first side; and
a deoxidized top surface of the substrate-side copper bump;
a semiconductor chip bonded to the substrate, wherein the semiconductor chip includes at least one chip-side copper bump aligned opposite the substrate-side copper bump.

18. The semiconductor device of claim 17, wherein the chip-side copper bump comprises:
an oxidized copper sidewall on a first side of the chip-side copper bump;
a deoxidized copper sidewall on a second side of the chip-side copper bump, opposite the first side; and
a deoxidized top surface of the chip-side copper bump, wherein the deoxidized copper sidewall and top surface of the chip-side copper bump are aligned with the corresponding deoxidized copper sidewall and top surface of the substrate-side copper bump.

19. The semiconductor device of claim 17, wherein the bonding between the substrate-side copper bump and the chip-side copper bump is formed by reflowed solder material, creating an electrical and mechanical connection between the semiconductor chip and the substrate.

20. The semiconductor device of claim 17, wherein the oxidized copper sidewall on the substrate-side copper bump has an oxide layer with a thickness of A nanometers, and the deoxidized copper sidewall on the substrate-side copper bump has an oxide layer with a thickness of B nanometers, wherein the difference in oxide thickness, A minus B, is at least 3 nanometers.
